(19) United States
(12) Patent Application Publication
(10) Pub. No.: US 2008/0277792 A1
(43) Pub. Date: Nov. 13, 2008

(54) Semiconductor Device and Method for Manufacturing the Same

(76) Inventors: SANG HEE LEE, Eumseong-gun (KR); Gab Hwan Cho, Icheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 12/117,442

(22) Filed: May 8, 2008

(30) Foreign Application Priority Data
May 10, 2007 (KR) 10-2007-0045626

(51) Int. Cl. H01L 23/528; H01L 21/768

(52) U.S. Cl. 257/754; 438/647; 257/E23.151; 257/E21.582

(57) ABSTRACT

Overlapping dummy patterns for a semiconductor device are disclosed. According to an embodiment, a first dummy pattern is formed on a substrate; a second dummy pattern is formed to be overlapped with the first dummy pattern; and a third dummy pattern is formed to provide an electrical connection between the first dummy pattern and the second dummy pattern.

### CROSS-REFERENCE TO RELATED APPLICATION

The present application claims the benefit under 35 U.S.C. §119 of Korean Patent Application No. 10-2007-0045626, filed May 10, 2007, which is hereby incorporated by reference in its entirety.

### BACKGROUND

A semiconductor device is generally configured of a multi-layer structure, wherein each layer of such a multi-layer structure is typically formed by a deposition method or a sputtering method, and then is patterned through a lithography process.

However, there has been a case where some problems occur due to differences in pattern size and pattern density on a substrate of the semiconductor device. Therefore, there is being developed techniques to form a dummy pattern together with a main pattern.

### BRIEF SUMMARY

Embodiments of the present invention provide a semiconductor device and a method for manufacturing the same capable of providing a new shape of dummy pattern where dummy patterns can be overlapped.

Also, embodiments of the present invention provide a semiconductor device and a method for manufacturing the same capable of securing uniformity of patterns between a main pattern and a dummy pattern by increasing density of the dummy pattern by overlapping the dummy patterns.

According to an embodiment, a semiconductor device and a method for manufacturing the same are provided capable of raising a pattern.

According to an embodiment, a semiconductor device and a method for manufacturing the same are provided capable of simplifying a design process and a manufacturing process.

A semiconductor device according to an embodiment can include a first dummy pattern formed on a substrate; a second dummy pattern formed to be overlapped with the first dummy pattern; and a third dummy pattern formed for electrically connecting the first dummy pattern to the second dummy pattern.

A method for manufacturing a semiconductor device according to an embodiment can include: forming a first dummy pattern on a substrate; forming a second dummy pattern overlapping the first dummy pattern; and forming a third dummy pattern connected to the first dummy pattern and the second dummy pattern.

Also, a semiconductor device according to an embodiment can include a main pattern formed in a first region on a substrate; and overlapping dummy patterns formed in a second region other than the region where the main pattern is formed.

### BRIEF DESCRIPTION OF THE DRAWINGS

FIG. 1 is a plan view of a semiconductor device according to an embodiment.

FIG. 2 is a cross-sectional view of a semiconductor device taken along line I-I′ of FIG. 1 according to an embodiment.

FIGS. 3A to 3D are concept views of a layout method according to an embodiment.

FIG. 4 is a plan view of a semiconductor device according to an embodiment.

FIG. 5 is a cross-sectional view of a semiconductor device taken along line II-II′ of FIG. 4 according to an embodiment.

FIG. 6 is a plan view of a semiconductor device layout pattern according to an embodiment.

### DETAILED DESCRIPTION

Hereinafter, a semiconductor device and a method for manufacturing the same according to embodiments of the present invention will be described with reference to the accompanying drawings.

In the description of embodiments, it will be understood that when a layer (or film) is referred to as being ‘on’ another layer or substrate, it can be directly on another layer or substrate, or intervening layers may also be present. Further, it will be understood that when a layer is referred to as being ‘under’ another layer, it can be directly under another layer, or one or more intervening layers may also be present. In addition, it will also be understood that when a layer is referred to as being ‘between’ two layers, it can be the only layer between the two layers, or one or more intervening layers may also be present.

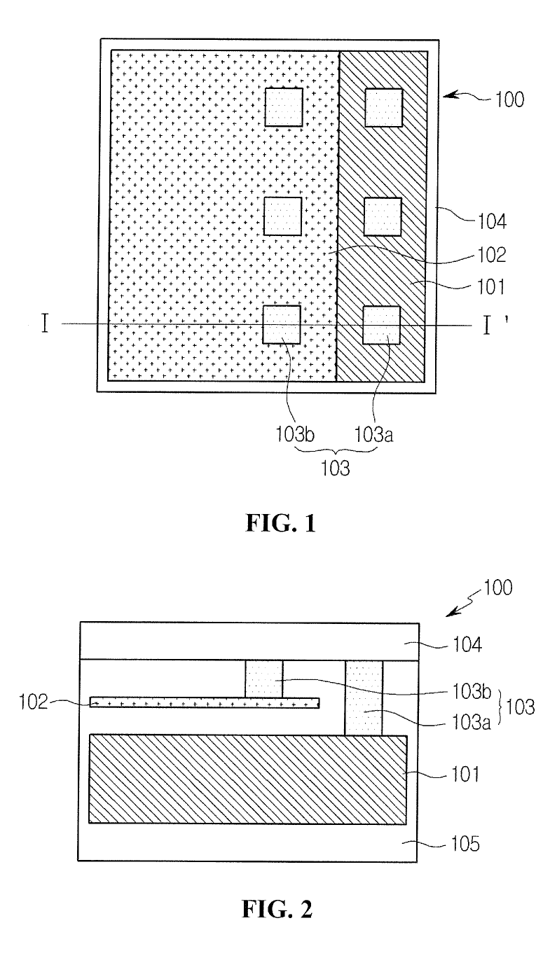

FIG. 1 is a plan view of a semiconductor device according to a first embodiment and FIG. 2 is a cross-sectional view taken along a line I-I′ of the semiconductor device according to the first embodiment.

Referring to FIGS. 1 and 2, a semiconductor device can include a first dummy pattern 101 formed on a substrate 105; a second dummy pattern 102 formed to be overlapped with the first dummy pattern 101; and a third dummy pattern 103 formed to electrically connect with the first dummy pattern 101 and the second dummy pattern 102.

In a further embodiment, the semiconductor device can include a fourth dummy pattern 104 formed on the third dummy pattern 103.

The first dummy pattern 101, the second dummy pattern 102, the third dummy pattern 103 and the fourth dummy pattern 104 can be considered as overlapping dummy patterns 100. The overlapping aspect relates to the patterns being formed directly above each other in the various layers of the multilayer semiconductor device structure.

In one embodiment, the first dummy pattern 101 can be an active dummy pattern, the second dummy pattern 102 can be a polysilicon dummy pattern, the third dummy pattern 103 can be a contact dummy pattern, and the fourth dummy pattern 104 can be a metal dummy pattern. However, embodiments are not limited thereto.

With the semiconductor device according to an embodiment, parasitic capacitance can be inhibited by using a contact dummy pattern, making it possible to provide a new shape of dummy pattern where dummy patterns can be overlapped. That is, overlapping dummy pattern layers can be formed bye using a contact dummy pattern to reduce parasitic capacitance.

For example, the third dummy pattern 103 can include a fifth dummy pattern 103a connecting the first dummy pattern 101 to the fourth dummy pattern 104, and a sixth dummy pattern 103b connecting the second dummy pattern 102 to the fourth dummy pattern 104.

In other words, despite the overlap between the first dummy pattern 101 and the second dummy pattern 102, a difference in potential between the first dummy pattern 101 and the second dummy pattern 102 can be inhibited by the contact dummy patterns of the fifth dummy pattern 103a and the sixth dummy pattern 103b being electrically connected to each other through the fourth dummy pattern 104 where the fourth dummy pattern is a conductive material. Accordingly, it is possible to provide a new shape of dummy pattern where dummy patterns can be overlapped.

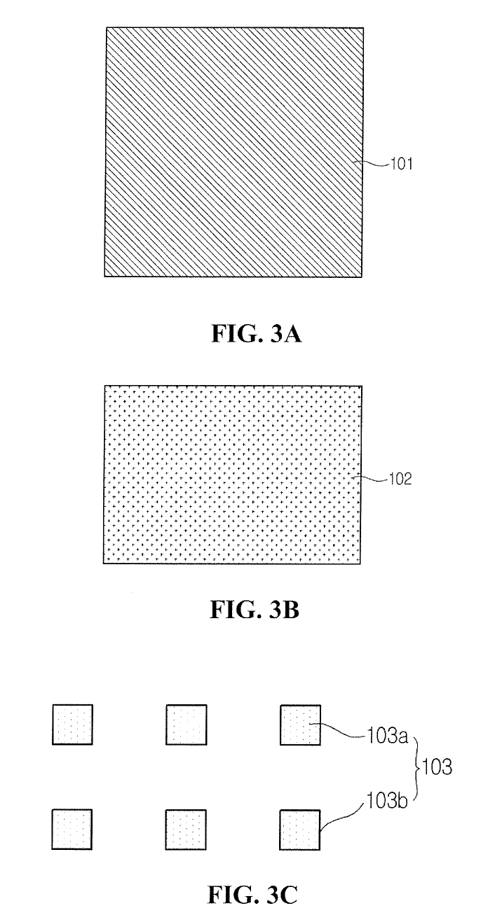

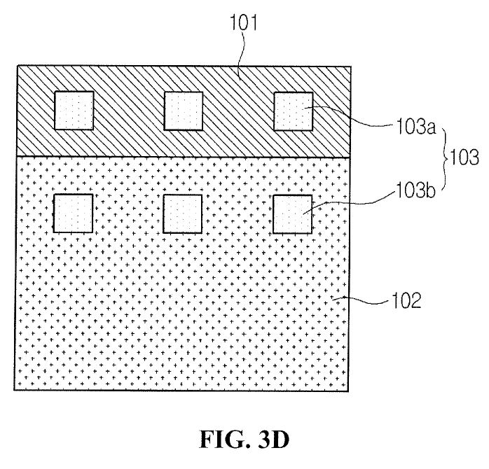

Hereinafter, a method for manufacturing a semiconductor device according to an embodiment will be described with reference to FIG. 2 and FIGS. 3A to 3D.

Referring to FIG. 2, a first dummy pattern 101 can be formed on a substrate 105. The first dummy pattern 101 can have a plan view layout as shown in FIG. 3A. In one embodiment, the first dummy pattern 101 can be an active layer dummy pattern. However, embodiments are not limited thereto.

A second dummy pattern 102 can be formed to be overlapped with the first dummy pattern 101, as shown in FIG. 2. The second dummy pattern can have a plan view layout as shown in FIG. 3B.

In an embodiment, the second dummy pattern 102 can be formed using a pattern layout method where the first dummy pattern 101 is contracted or has at least one side shrunk down and the pattern type changed as shown in FIG. 3B. The second dummy pattern 102 can be a poly dummy pattern. However, embodiments are not limited thereto. When the first dummy pattern 101 is an active layer pattern and the second dummy pattern 102 is a poly layer pattern, a dielectric layer may be fabricated between the two patterns. This structure can result in the generation of capacitance.

In the conventional design rules, the overlap between the dummy patterns is not allowed due to the generation of capacitance. However, according to embodiments of the present invention, the overlap between the dummy patterns is possible.

In particular, according to an embodiment, a third dummy pattern 103 is used to electrically connect the first dummy pattern 101 to the second dummy pattern 102. The third dummy pattern 103 can be a contact dummy pattern. However, embodiments are not limited thereto. The third dummy pattern can have a plan view layout as shown in FIG. 3C.

Referring to FIG. 2 and FIG. 3C, in an embodiment, a step forming the third dummy pattern 103 can include forming a fifth dummy pattern 103a connected to the first dummy pattern 101, and a sixth dummy pattern 103b connected to the second dummy pattern 102. FIG. 3D shows a plan view of the first dummy pattern 101 with the second dummy pattern 102 overlapping the first dummy pattern 101, and the third dummy patterns 103a and 103b connected to the first dummy pattern 101 and the second dummy pattern 102, respectively.

Next, a fourth dummy pattern 104 can be formed on the third dummy pattern 103. The fourth dummy pattern 104 can be a metal dummy pattern and can allow the first dummy pattern 101 and second dummy pattern 102 to be electrically connected through the third dummy pattern 103.

Accordingly, parasitic capacitance can be inhibited by the contact dummy pattern, making it possible to provide a semiconductor device and a method for manufacturing the same capable of providing a new shape of dummy pattern where dummy patterns can be overlapped.

Also, because dummy patterns can be overlapped, the density of the dummy patterns can be increased. In an embodiment, this can make it possible to secure uniformity of patterns between a main pattern and a dummy pattern.

Also, a design process and a manufacturing process can be simplified by a replacement process between the dummy patterns. For example, during mask layout design, a first layer pattern can be easily used for a second layer pattern by a replacement of pattern type and reduction in size of as little as one side.

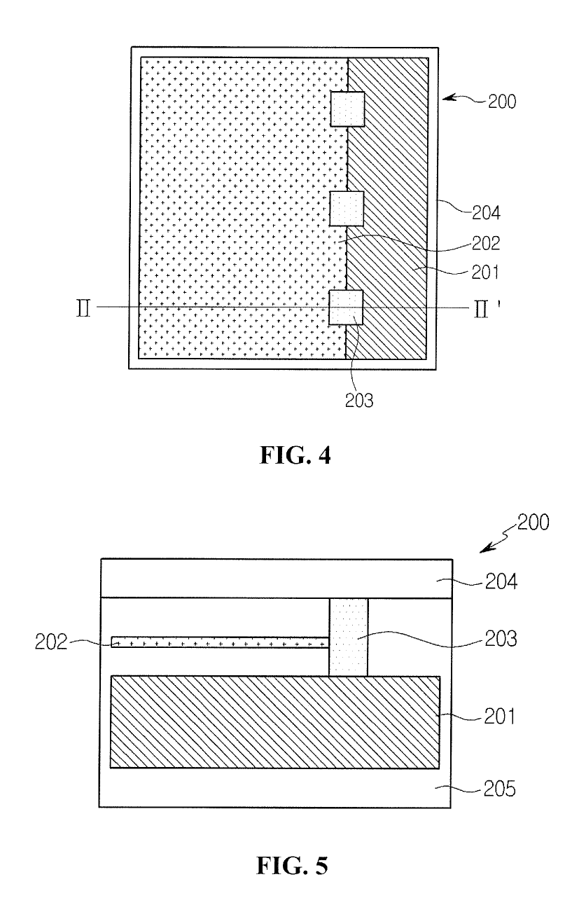

FIG. 4 is a plan view of a semiconductor device according to a second embodiment and FIG. 5 is a cross-sectional view taken along a line II-II′ of the semiconductor device according to the second embodiment.

Referring to FIGS. 4 and 5, a semiconductor device according to the second embodiment can include a first dummy pattern 201 formed on a substrate 205; a second dummy pattern 202 formed to be overlapped with the first dummy pattern 201; and a third dummy pattern 203 formed to electrically connect with the first dummy pattern 201 and the second dummy pattern 202.

In a further embodiment, the semiconductor device can include a fourth dummy pattern 204 formed on the third dummy pattern 203.

In one embodiment, the first dummy pattern 201 can be an active dummy pattern, the second dummy pattern 202 can be a poly dummy pattern, the third dummy pattern 203 can be a contact dummy pattern, and the fourth dummy pattern 204 can be a metal dummy pattern. However, embodiments are not limited thereto.

The first dummy pattern 201, the second dummy pattern 202, the third dummy pattern 203 and the fourth dummy pattern 204 can be considered overlapping dummy patterns 200.

The second embodiment can adopt many of the characteristics of the first embodiment. However, the second embodiment can provide a different third dummy pattern.

According to this embodiment, the third dummy pattern 203 can be formed to connect an edge of the second dummy pattern 202 to the first dummy pattern 201, such as shown in FIGS. 4 and 5. However, implementations are not limited thereto.

For example, in another embodiment, the third dummy pattern 203 can be formed to connect the edge of the first dummy pattern 201 to the second dummy pattern 202. Here, as long as the dummy contact pattern 203 reaching the first dummy pattern 201 also touches the second dummy pattern 202, the dummy contact pattern 203 electrically connects the first dummy pattern 201 to the second dummy pattern 202.

With the semiconductor device and the method for manufacturing the same according to the second embodiment, parasitic capacitance can be inhibited by the contact dummy pattern, making it possible to provide a new shape of dummy pattern where dummy patterns can be overlapped.

Despite the overlap between the first dummy pattern 201 and the second dummy pattern 202, a difference in potential can be inhibited from occurring by the contact dummy pattern of the third dummy pattern 203.

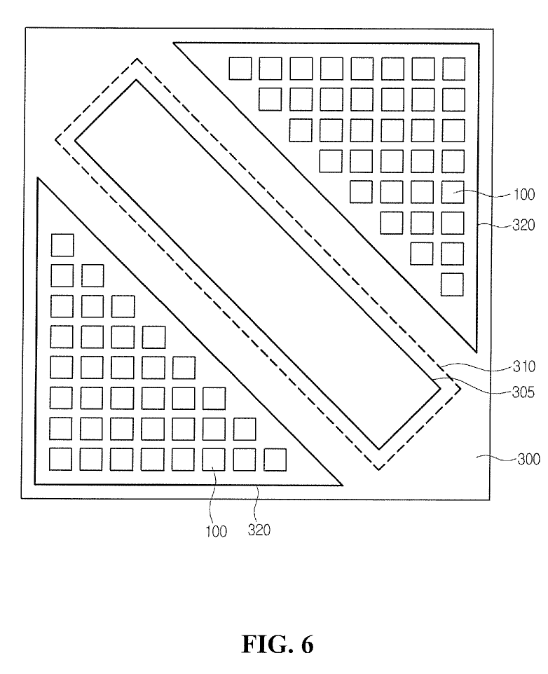

Referring to FIG. 6, a semiconductor device according to an embodiment can include a main pattern 305 formed in a first region 310 on a substrate 300; and overlapping dummy patterns 100 formed in a second region 320, which is a region other than the region where the main pattern 305 is formed.

In an embodiment, the main pattern 305 can be a metal main pattern. However, embodiments are not limited thereto. The first region 310 can be a region where dummy patterns are forbidden according to design layout rules.

According to many embodiments, the dummy patterns are inserted by distinguishing a region where dummy patterns can be overlapped from a region where dummy patterns cannot be overlapped, making it possible to increase pattern density.

The overlapping dummy patterns can adopt the form of the overlapping dummy patterns 100 and 200 described above.

For example, the overlapping dummy patterns can include first dummy patterns 101 or 201 formed on the substrate 300; second dummy patterns 102 or 202 formed to be overlapped with the first dummy patterns 101 or 201; and third dummy patterns formed to connect the first dummy patterns 101 or 201 to the second dummy patterns 102 or 202. Also, the overlapping dummy patterns can include fourth dummy patterns 104 or 204 formed on the third dummy patterns 103 or 203.

For example, in one embodiment, when adopting the dummy patterns 100 overlapped such as shown in the embodiment illustrated in FIG. 2, the third dummy pattern 103 can include a fifth dummy pattern 103a connecting the first dummy pattern 101 to the fourth dummy pattern 104, and a sixth dummy pattern 103b connecting the second dummy pattern 102 to the fourth dummy pattern 104.

Also, for example, in another embodiment, when adopting the dummy patterns 200 overlapped such as shown in the embodiment illustrated in FIG. 5, the third dummy pattern 203 can be formed to connect an edge of the second dummy pattern 202 to the first dummy pattern 201. Alternatively, the third dummy pattern 203 can be formed to connect an edge of the first dummy pattern 201 to the second dummy pattern 202.

In an embodiment, the dummy patterns can be inserted in regions where multiple layers of dummy patterns can be overlapped, making it possible to remarkably raise density of pattern.

For example, the metal dummy pattern cannot be formed in the region where the metal main pattern is formed, Therefore, according to an embodiment, the active dummy pattern and the poly dummy pattern will also not be formed in the region where the metal main pattern is formed. Instead, the overlapped dummy pattern is formed in the region where the overlap is allowed, making it possible to remarkably raise pattern density.

Accordingly, parasitic capacitance can be inhibited between the first dummy pattern and the second dummy pattern by use of the contact dummy pattern, making it possible to provide a semiconductor device and a method for manufacturing the same capable of providing a new shape of dummy pattern where dummy patterns can be overlapped.

Also, according to embodiments, the dummy patterns can be overlapped to raise the density of the dummy patterns, making it possible to secure uniformity of the pattern between a main pattern and a dummy pattern.

According to many embodiments, the dummy patterns are inserted in a region determined by distinguishing a region where the dummy patterns can be overlapped from a region where the dummy patterns cannot be overlapped.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device, comprising:
a first dummy pattern on a substrate;
a second dummy pattern formed to be overlapped with the first dummy pattern; and
a third dummy pattern for electrically connecting the first dummy pattern to the second dummy pattern.

2. The semiconductor device according to claim 1, further comprising a fourth dummy pattern on the third dummy pattern.

3. The semiconductor device according to claim 2, wherein the third dummy pattern comprises:
a fifth dummy pattern connecting the first dummy pattern to the fourth dummy pattern; and
a sixth dummy pattern connecting the second dummy pattern to the fourth dummy pattern.

4. The semiconductor device according to claim 2, wherein the fourth dummy pattern comprises a metal layer dummy pattern.

5. The semiconductor device according to claim 1, wherein the third dummy pattern connects an edge of the second dummy pattern to the first dummy pattern.

6. The semiconductor device according to claim 1, wherein the third dummy pattern connects an edge of the first dummy pattern to the second dummy patter.

7. The semiconductor device according to claim 1, wherein the first dummy pattern comprises an active layer dummy pattern, the second dummy pattern comprises a poly dummy pattern, and the third dummy pattern comprises a contact dummy pattern.

8. A method for manufacturing a semiconductor device comprising:
forming a first dummy pattern on a substrate;
forming a second dummy pattern overlapping the first dummy pattern; and
forming a third dummy pattern connected to the first dummy pattern and the second dummy pattern.

9. The method according to claim 8, further comprising forming a fourth dummy pattern on the third dummy pattern.

10. The method according to claim 9, wherein forming the third dummy pattern comprises:
forming a fifth dummy pattern connected to the first dummy pattern, wherein the fifth dummy pattern connects the first dummy pattern to the fourth dummy pattern; and
forming a sixth dummy pattern connected to the second dummy pattern, wherein the sixth dummy pattern connects the second dummy pattern to the fourth dummy pattern,
wherein by connecting the first dummy pattern and the second dummy pattern to the fourth dummy pattern, the third dummy pattern connects the first dummy pattern to the second dummy pattern.

11. The method according to claim 9, wherein the first dummy pattern comprises an active layer dummy pattern, the second dummy pattern comprises a poly dummy pattern, the third dummy pattern comprises a contact dummy pattern, and the fourth dummy pattern comprises a metal dummy pattern.

12. The method according to claim 8, wherein the third dummy pattern is formed to connect an edge of the second dummy pattern to the first dummy pattern.

13. The method according to claim 8, wherein the third dummy pattern is formed to connect an edge of the first dummy pattern to the second dummy pattern.

14. A semiconductor device, comprising:
a main pattern on a first region on a substrate; and
overlapping dummy patterns on a second region of the substrate.

15. The semiconductor device according to claim 14, wherein the main pattern comprises a metal main pattern.

16. The semiconductor device according to claim 15, wherein the overlapping dummy patterns comprise:
a first dummy pattern on a substrate;
a second dummy pattern formed to be overlapped with the first dummy pattern; and
a third dummy pattern for electrically connecting the first dummy pattern to the second dummy pattern.

17. The semiconductor device according to claim 16, further comprising a fourth dummy pattern on the third dummy pattern.

18. The semiconductor device according to claim 17, wherein the third dummy pattern comprises:
a fifth dummy pattern connecting the first dummy pattern to the fourth dummy pattern; and
a sixth dummy pattern connecting the second dummy pattern to the fourth dummy pattern.

19. The semiconductor device according to claim 16, wherein the third dummy pattern connects an edge of the second dummy pattern to the first dummy pattern.

20. The semiconductor device according to claim 16, wherein the third dummy pattern connects an edge of the first dummy pattern to the second dummy pattern.
